(19) United States
(12) Patent Application Publication
(10) Pub. No.: US 2025/0040395 A1
(43) Pub. Date: Jan. 30, 2025

(54) DISPLAY APPARATUS

(71) Applicant: Samsung Display Co., Ltd., Yongin-si (KR)

(72) Inventors: Seokgyu Yoon, Yongin-si (KR); Jinsoo Jung, Yongin-si (KR); Sujeong Kim, Yongin-si (KR); Hwasook Ryu, Yongin-si (KR); Hyejin Jung, Yongin-si (KR)

(21) Appl. No.: 18/780,018

(22) Filed: Jul. 22, 2024

(30) Foreign Application Priority Data
Jul. 26, 2023 (KR) 10-2023-0097697

(51) Int. Cl. H10K 59/60; H10K 59/126; H10K 59/38; H10K 59/40; H10K 59/80; H10K 102/00

(52) U.S. Cl. CPC H10K 59/60; H10K 59/126; H10K 59/38; H10K 59/40; H10K 59/8731; H10K 59/8791; H10K 2102/351

(57) ABSTRACT

A display apparatus includes: a substrate having an emission area and a sensing area; a light-emitting element over the substrate and overlapping the emission area; a light-receiving element over the substrate and overlapping the sensing area; an upper layer over the light-emitting element and the light-receiving element and comprising a sensing opening overlapping the light-receiving element; and a convex light-transmitting portion filling the sensing opening and comprising a convex upper surface.

### CROSS-REFERENCE TO RELATED APPLICATION

The present application claims priority to and the benefit of Korean Patent Application No. 10-2023-0097697, filed on Jul. 26, 2023, in the Korean Intellectual Property Office, the entire disclosure of which is incorporated herein by reference.

### BACKGROUND

### 1. Field

Aspects of one or more embodiments relate to a display apparatus.

### 2. Description of the Related Art

In general, a display apparatus includes a light-emitting element, such as an organic light-emitting diode, and a thin-film transistor on a substrate, and operates by causing display elements to emit light.

In some display apparatuses, each pixel of the display apparatus may have a light-emitting element, such as an organic light-emitting diode, in which an intermediate layer including an emission layer is located between a pixel electrode and an opposite electrode. In the display apparatus, whether or not to emit light or the degree of light emission of each pixel is generally controlled through the thin-film transistor electrically connected to the pixel electrode. Some layers included in the intermediate layer of such a display element may be commonly provided for a plurality of light-emitting elements.

The above information disclosed in this Background section is only for enhancement of understanding of the background and therefore the information discussed in this Background section does not necessarily constitute prior art.

### SUMMARY

Aspects of one or more embodiments include a display apparatus including a light-receiving element with relatively improved detectivity. However, such characteristics are merely examples, and embodiments according to the present disclosure are not limited thereto.

Additional aspects will be set forth in part in the description which follows and, in part, will be more apparent from the description, or may be learned by practice of the presented embodiments of the disclosure.

According to some embodiments of the present disclosure, a display apparatus includes a substrate including an emission area and a sensing area, a light-emitting element arranged over the substrate and overlapping the emission area, a light-receiving element arranged over the substrate and overlapping the sensing area, an upper layer arranged over the light-emitting element and the light-receiving element and including a sensing opening overlapping the light-receiving element, and a convex light-transmitting portion filling the sensing opening and including a convex upper surface.

According to some embodiments, the upper layer may be a light-blocking layer including a light-blocking material, wherein the light-blocking layer may include a first light-blocking layer opening overlapping the light-emitting element and a second light-blocking layer opening overlapping the light-receiving element, wherein the sensing opening may be the second light-blocking layer opening, and the convex light-transmitting portion may be arranged in the second light-blocking layer opening.

According to some embodiments, the display apparatus may further include a color filter layer filling the first light-blocking layer opening, wherein the color filter layer may include a first color filter, a second color filter, and a third color filter that are configured to transmit light of different colors from one another.

According to some embodiments, the convex light-transmitting portion may include the same material as at least one of the first color filter, the second color filter, or the third color filter.

According to some embodiments, the convex light-transmitting portion may be configured to transmit light having a wavelength range of 495 nm to 580 nm.

According to some embodiments, based on a thickness direction of the substrate, a cross-section of the convex light-transmitting portion may have a shape that becomes thicker toward a center of the convex light-transmitting portion, wherein a central portion of the convex light-transmitting portion may be thicker than the light-blocking layer.

According to some embodiments, the display apparatus may further include an overcoat layer arranged over the light-blocking layer and the color filter layer, wherein a refractive index of the convex light-transmitting portion may be higher than that of the overcoat layer.

According to some embodiments, a difference between the refractive index of the convex light-transmitting portion and the refractive index of the overcoat layer may be 0.1 to 0.3.

According to some embodiments, the display apparatus may further include a thin film encapsulation layer covering the light-emitting element and the light-receiving element, and an input sensing layer arranged between the thin film encapsulation layer and the light-blocking layer.

According to some embodiments, the display apparatus may further include an input sensing layer arranged over the light-emitting element and the light-receiving element, wherein the input sensing layer may include a first conductive layer, a first inorganic insulating layer arranged on the first conductive layer, a second conductive layer arranged on the first inorganic insulating layer, and a second inorganic insulating layer arranged on the second conductive layer, wherein the first conductive layer may include a first conductive layer opening overlapping the light-receiving element, and the second conductive layer may include a second conductive layer opening overlapping the light-receiving element, wherein the upper layer may be at least one of the first conductive layer or the second conductive layer.

According to some embodiments, the display apparatus may further include a polarizing layer arranged on the input sensing layer.

According to some embodiments, the upper layer may be the first conductive layer, the sensing opening may be the first conductive layer opening, and the convex light-transmitting portion may be arranged in the first conductive layer opening.

According to some embodiments, the first inorganic insulating layer may cover the convex light-transmitting portion.

According to some embodiments, a refractive index of the convex light-transmitting portion may be higher than that of the first inorganic insulating layer.

According to some embodiments, a difference between the refractive index of the convex light-transmitting portion and the refractive index of the first inorganic insulating layer may be 0.1 to 0.3.

According to some embodiments, the upper layer may be the second conductive layer, the sensing opening may be the second conductive layer opening, and the convex light-transmitting portion may be arranged in the second conductive layer opening.

According to some embodiments, the second inorganic insulating layer may cover the convex light-transmitting portion.

According to some embodiments, a refractive index of the convex light-transmitting portion may be higher than that of the second inorganic insulating layer.

According to some embodiments, a difference between the refractive index of the convex light-transmitting portion and the refractive index of the second inorganic insulating layer may be 0.1 to 0.3.

According to some embodiments, the display apparatus may further include a thin film encapsulation layer covering the light-emitting element and the light-receiving element and arranged under the input sensing layer.

### BRIEF DESCRIPTION OF DRAWINGS

The above and other aspects, features, and characteristics of certain embodiments of the disclosure will be more apparent from the following description taken in conjunction with the accompanying drawings, in which:

FIG. 1 is a schematic plan view of a portion of a display apparatus according to some embodiments;

FIG. 2 is a schematic cross-sectional view of the display apparatus of FIG. 1, taken along a line A-A′ of FIG. 1 according to some embodiments;

FIG. 3A is a schematic cross-sectional view of a display panel of a display apparatus according to some embodiments;

FIG. 3B is a schematic cross-sectional view of a display panel of a display apparatus according to some embodiments;

FIG. 4 is an equivalent circuit diagram of a pixel circuit electrically connected to a light-emitting element included in a pixel of a display apparatus according to some embodiments;

FIG. 5 is a schematic cross-sectional view of a portion of a display apparatus according to some embodiments;

FIG. 6 is a schematic plan view of an input sensing layer of a display apparatus according to some embodiments;

FIG. 7 is a schematic plan view of a portion of a display apparatus according to some embodiments, and is an enlarged schematic plan view of a region B of FIG. 1;

FIG. 8 is a schematic cross-sectional view of a portion of a display apparatus according to some embodiments, taken along a line C-C′ of FIG. 7;

FIG. 9 is a schematic cross-sectional view of a portion of a display apparatus according to some embodiments; and

FIG. 10 is a schematic cross-sectional view of a portion of a display apparatus according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in the written description. Aspects and features of one or more embodiments and methods of accomplishing the same will become apparent from the following detailed description of the one or more embodiments, taken in conjunction with the accompanying drawings. However, the present embodiments may have different forms and should not be construed as being limited to the descriptions set forth herein.

Aspects of one or more embodiments will be described below in more detail with reference to the accompanying drawings. Those elements that are the same or are in correspondence with each other are rendered the same reference numeral regardless of the figure number, and redundant descriptions thereof are omitted.

While such terms as “first” and “second” may be used to describe various elements, such elements must not be limited to the above terms. The above terms are used only to distinguish one element from another.

The singular forms “a,” “an,” and “the” as used herein are intended to include the plural forms as well unless the context clearly indicates otherwise.

It will be understood that the terms “include,” “comprise,” and “have” as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

When an embodiment may be implemented differently, a certain process order may be performed differently from the described order. For example, two consecutively described processes may be performed substantially at the same time or performed in an order opposite to the described order.

It will be further understood that, when layers, regions, or elements are referred to as being connected to each other, they may be directly connected to each other or may be indirectly connected to each other with intervening layers, regions, or elements therebetween. For example, when layers, regions, or elements are referred to as being electrically connected to each other, they may be directly electrically connected to each other or may be indirectly electrically connected to each other with intervening layers, regions, or elements therebetween.

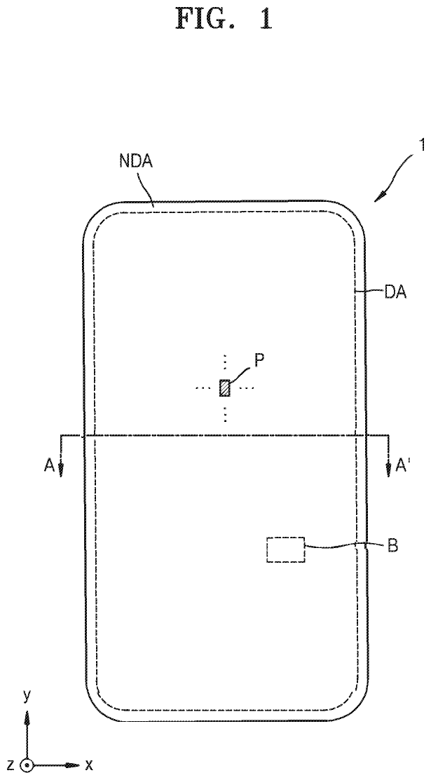

FIG. 1 is a schematic plan view of a portion of a display apparatus 1 according to some embodiments.

Referring to FIG. 1, the display apparatus 1 includes a display area DA and a peripheral area NDA outside (e.g., in a periphery or outside a footprint of) the display area DA. A plurality of pixels P including display elements are arranged in the display area DA, and the display apparatus 1 may display images by using light emitted from the plurality of pixels P arranged in the display area DA. The peripheral area NDA is a non-display area where display elements are not arranged, and the display area DA may be entirely surrounded by the peripheral area NDA.

Although FIG. 1 shows the display apparatus 1 including a flat display surface, one or more embodiments are not limited thereto. According to some embodiments, the display apparatus 1 may include a stereoscopic display surface or a curved display surface.

When the display apparatus 1 includes a stereoscopic display surface, the display apparatus 1 includes a plurality of display areas indicating different directions, and for example, may include a polygonal columnar display surface. According to some embodiments, when the display apparatus 1 includes a curved display surface, the display apparatus 1 may be implemented in various forms, such as a flexible, foldable, or rollable display apparatus.

In addition, according to some embodiments, FIG. 1 shows the display apparatus 1 applicable to a mobile phone terminal. According to some embodiments, electronic modules, a camera module, a power module, and the like mounted on a mainboard may be arranged together with the display apparatus 1 in a bracket/case, etc., thereby constituting a mobile phone terminal. The display apparatus 1 described herein may be applied to large-sized electronic devices, such as a television and a monitor, and may also be applied to small and medium-sized electronic devices, such as a tablet personal computer, a vehicle navigation system, a game console, and a smartwatch.

Although FIG. 1 shows a case in which the display area DA of the display apparatus 1 has a quadrangular shape with round corners, according to some embodiments, a shape of the display area DA may be a circle, an oval, or a polygon, such as a triangle or a pentagon.

Although an organic light-emitting display apparatus is illustrated below as the display apparatus 1 according to some embodiments, the display apparatus 1 described herein is not limited thereto. According to some embodiments, the display apparatus 1 described herein may be a display apparatus, such as an inorganic light-emitting display (or an inorganic electroluminescent (EL) display) or a quantum dot light-emitting display. For example, an emission layer of a display element in the display apparatus 1 may include an organic material, an inorganic material, quantum dots, an organic material and quantum dots, or an inorganic material and quantum dots.

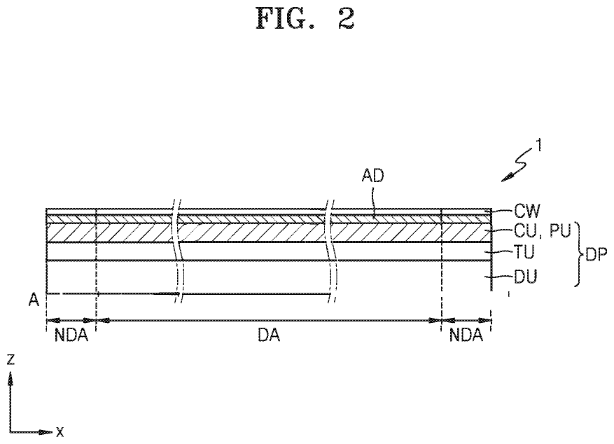

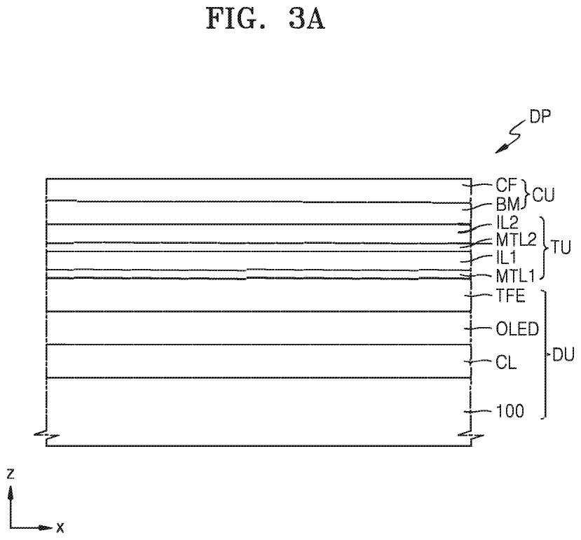

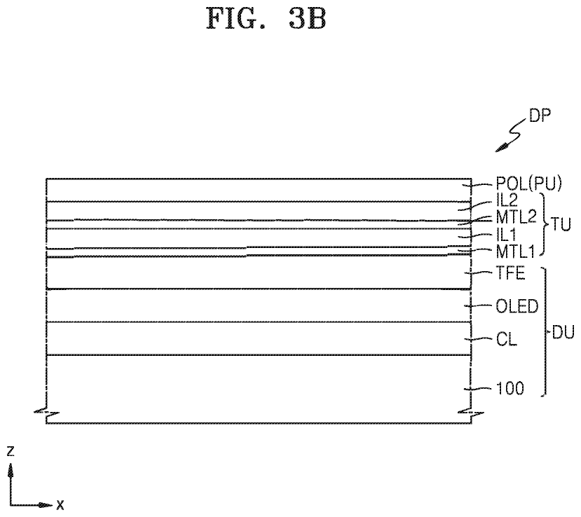

FIG. 2 is a schematic cross-sectional view of the display apparatus 1 of FIG. 1, taken along a line A-A′ of FIG. 1. FIG. 3A is a schematic cross-sectional view of a display panel DP of a display apparatus according to some embodiments. FIG. 3B is a schematic cross-sectional view of the display panel DP of a display apparatus according to some embodiments. FIGS. 2 to 3B are simplified to describe the lamination relationship of a functional panel and/or functional layers constituting a display apparatus.

Referring to FIG. 2, the display apparatus 1 according to some embodiments may include a display layer DU, an input sensing layer TU, an optical functional layer, a color filter member CU, a polarizing member PU, and a cover window CW. At least some of the display layer DU, the input sensing layer TU, the color filter member CU, the polarizing member PU, and the cover window CW may be formed by successive processes, or at least some thereof may be coupled to each other through an adhesive member AD. The adhesive member AD of FIG. 2 may be an optical clear adhesive (OCA). However, one or more embodiments are not limited thereto, and the adhesive member AD described below may include a typical adhesive or a typical pressure sensitive adhesive. According to some embodiments, the cover window CW may be replaced with another element or may be omitted.

According to some embodiments, the input sensing layer TU is directly on the display layer DU. As used herein, the description “an element B is directly located on an element A” means that a separate adhesive layer/adhesive member is not located between the element A and the element B. After the element A is formed, the element B is formed on a base surface provided from the element A through a successive process.

According to some embodiments, a structure including the display layer DU, the input sensing layer TU, and the color filter member CU, or a structure including the display layer DU, the input sensing layer TU, and the polarizing member PU may be defined as the display panel DP. For example, as shown in FIG. 2, the adhesive member AD may be between the display panel DP and the cover window CW.

The display layer DU generates an image, and the input sensing layer TU obtains coordinate information regarding an external input (e.g., a touch event). Although not separately shown, the display panel DP according to some embodiments may further include a protection member located under the display layer DU. The protection member and the display panel DP may be coupled to each other through an adhesive member. According to some embodiments, the optical functional layer may be additionally located on the input sensing layer TU. The optical functional layer may relatively improve light efficiency. The optical functional layer may relatively improve frontal light efficiency and/or lateral visibility of light emitted from a light-emitting element, for example, an organic light-emitting diode OLED.

According to some embodiments, the color filter member CU may be located between the input sensing layer TU and the cover window CW. The color filter member CU may include a color filter corresponding to an emission area of each pixel P and a light-blocking layer corresponding to a non-emission area between pixels P. According to some embodiments, the polarizing member PU may be located between the input sensing layer TU and the cover window CW instead of the color filter member CU. The polarizing member PU may include a polarizing layer, and the polarizing layer may reduce reflection of external light incident on the display panel DP.

Hereinafter, structures of the display layer DU, the input sensing layer TU, the color filter member CU, and the polarizing member PU will be described in more detail with reference to FIGS. 3A and 3B. Referring to FIGS. 3A and 3B, the display panel DP may include the display layer DU, the input sensing layer TU, and the color filter member CU. Alternatively, the display panel DP may include the display layer DU, the input sensing layer TU, and the polarizing member PU.

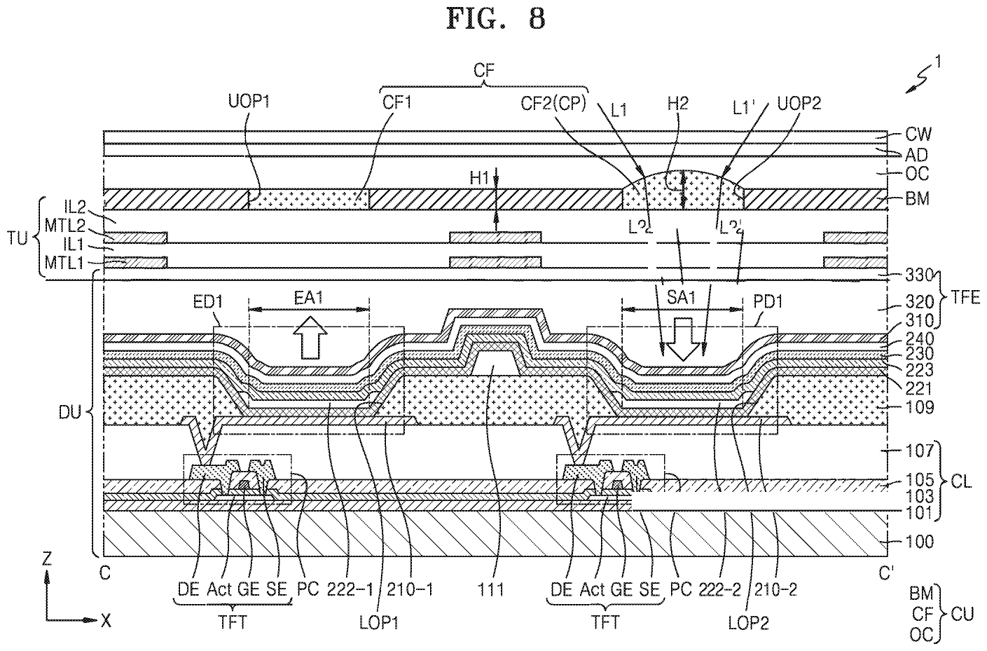

The display layer DU may have a circuit layer CL, a light-emitting element (e.g., the organic light-emitting diode OLED), and a thin film encapsulation layer TFE sequentially located on a substrate 100. The input sensing layer TU may be directly located on the thin film encapsulation layer TFE. The thin film encapsulation layer TFE may include at least one organic encapsulation layer 320 (of FIG. 8) and thus may provide a more planarized base surface. Accordingly, even when elements of the input sensing layer TU described below are formed through successive processes, a defect rate may be reduced.

The input sensing layer TU may have a multi-layer structure. The input sensing layer TU includes a sensing electrode, a trace line connected to the sensing electrode, and at least one insulating layer. The input sensing layer TU may sense an external input, for example, in a capacitive manner. In the disclosure, an operation method of the input sensing layer TU is not particularly limited, and according to some embodiments, the input sensing layer TU may sense an external input in an electromagnetic induction manner or a pressure sensing manner.

As shown in FIGS. 3A and 3B, the input sensing layer TU according to some embodiments may include a first conductive layer MTL1, a first inorganic insulating layer IL1, a second conductive layer MTL2, and a second inorganic insulating layer IL2. According to some embodiments, an additional insulating layer may be located between the first conductive layer MTL1 and the thin film encapsulation layer TFE.

According to some embodiments, each of the first conductive layer MTL1 and the second conductive layer MTL2 may have a single-layer structure or a stacked multi-layer structure. A conductive layer having a single-layer structure may include a metal layer or a transparent conductive layer. The metal layer may include molybdenum, silver, titanium, copper, aluminum, and an alloy thereof. The transparent conductive layer may include transparent conductive oxide, such as indium tin oxide (ITO), indium zinc oxide (IZO), zinc oxide (ZnO), indium tin zinc oxide (ITZO), etc. In addition, the transparent conductive layer may include a conductive polymer such as poly(3,4-ethylenedioxythiophene) (PEDOT), metal nanowires, graphene, etc. A conductive layer having a multi-layer structure may include multiple metal layers. The multiple metal layers may have, for example, a three-layer structure of titanium/aluminum/titanium (Ti/Al/Ti). The conductive layer having a multi-layer structure may include at least one metal layer and at least one transparent conductive layer.

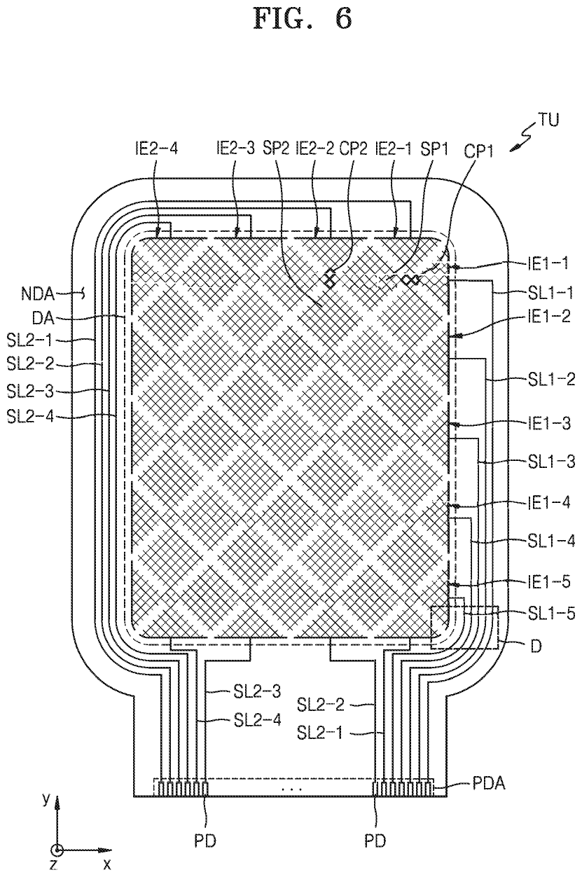

Each of the first conductive layer MTL1 and the second conductive layer MTL2 includes a plurality of patterns. Hereinafter, the first conductive layer MTL1 may be understood as including first conductive patterns, and the second conductive layer MTL2 may be understood as including second conductive patterns. The first conductive patterns and the second conductive patterns may form a sensing electrode shown in FIG. 6. According to some embodiments, the sensing electrode may have a mesh shape as will be described below with reference to FIG. 6 to prevent or reduce recognition by a user.

Each of the first inorganic insulating layer IL1 and the second inorganic insulating layer IL2 may have a single-layer or multi-layer structure. Each of the first inorganic insulating layer IL1 and the second inorganic insulating layer IL2 may include an inorganic material or a composite material. For example, at least one of the first inorganic insulating layer IL1 or the second inorganic insulating layer IL2 may include an inorganic layer. The inorganic layer may include at least one of aluminum oxide, titanium oxide, silicon oxide, silicon oxynitride, zirconium oxide, or hafnium oxide. According to some embodiments, the first inorganic insulating layer IL1 and/or the second inorganic insulating layer IL2 may be replaced with an organic insulating layer.

According to some embodiments, as shown in FIG. 3A, the color filter member CU may be directly located on the input sensing layer TU. The color filter member CU may include a light-blocking layer BM and a color filter layer CF on the light-blocking layer BM. The light-blocking layer BM may be a black matrix which at least partially absorbs externally reflected light or internally reflected light. The color filter layer CF may have a color corresponding to light emitted from an emission layer positioned below each color filter layer CF.

According to some embodiments, as shown in FIG. 3B, the polarizing member PU may be located on the input sensing layer TU instead of the color filter member CU. The polarizing member PU may include a polarizing layer POL. The polarizing layer POL may serve as an anti-reflection layer which reduces external light reflection to increase a contrast ratio and visibility. The polarizing layer POL may include a linear polarizer and a phase retarder.

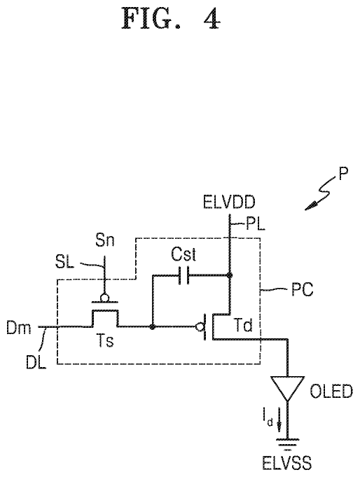

FIG. 4 is an equivalent circuit diagram of a pixel circuit PC electrically connected to a light-emitting element included in the pixel P of a display apparatus according to some embodiments.

Referring to FIG. 4, each pixel P includes the pixel circuit PC connected to a scan line SL and a data line DL and a light-emitting element (e.g., the organic light-emitting diode OLED) connected to the pixel circuit PC.

The pixel circuit PC includes a driving thin-film transistor Td, a switching thin-film transistor Ts, and a storage capacitor Cst. The switching thin-film transistor Ts is connected to the scan line SL and the data line DL and is configured to transmit a data signal Dm input through the data line DL to the driving thin-film transistor Td according to a scan signal Sn input through the scan line SL.

The storage capacitor Cst is connected to the switching thin-film transistor Ts and a driving voltage line PL and stores a voltage corresponding to a difference between a voltage received from the switching thin-film transistor Ts and a driving voltage ELVDD supplied to the driving voltage line PL.

The driving thin-film transistor Td is connected to the driving voltage line PL and the storage capacitor Cst, and may be configured to control a driving current 1a flowing through the organic light-emitting diode OLED from the driving voltage line PL, in response to a voltage value stored in the storage capacitor Cst. The organic light-emitting diode OLED may emit light having a certain luminance according to the driving current 1a.

Although FIG. 4 shows a case in which the pixel circuit PC includes two thin-film transistors and one storage capacitor, embodiments according to the present disclosure are not limited thereto. According to some embodiments, the pixel circuit PC may include seven thin-film transistors and one storage capacitor. According to some embodiments, the pixel circuit PC may include two or more storage capacitors. According to some embodiments, the pixel circuit PC may include additional components or fewer components than those described above, without departing from the spirit and scope of embodiments according to the present disclosure.

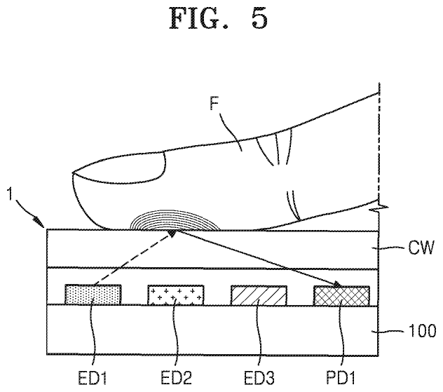

FIG. 5 is a schematic cross-sectional view of a portion of the display apparatus 1 according to some embodiments.

Referring to FIG. 5, the display apparatus 1 according to some embodiments may include a first light-emitting element ED1, a second light-emitting element ED2, a third light-emitting element ED3, and a first light-receiving element PD1. The first light-emitting element ED1, the second light-emitting element ED2, and the third light-emitting element ED3 may emit light of different colors from one another. For example, the first light-emitting element ED1 may emit green light, the second light-emitting element ED2 may emit red light, and the third light-emitting element ED3 may emit blue light.

As shown in FIG. 5, the display apparatus 1 may have the function of sensing an object that is in contact with the cover window CW, for example, a fingerprint of a finger F. Of light emitted from at least one of the first light-emitting element ED1, the second light-emitting element ED2, or the third light-emitting element ED3, at least a portion of reflected light reflected from a user's fingerprint may be re-incident on the first light-receiving element PD1, and thus, the first light-receiving element PD1 may detect the reflected light. For example, green light emitted from the first light-emitting element ED1 may be reflected from an object that is in contact with the cover window CW and be re-incident on the first light-receiving element PD1, and thus, the first light-receiving element PD1 may detect the re-incident green light.

FIG. 6 is a schematic plan view of the input sensing layer TU of a display apparatus according to some embodiments.

As shown in FIG. 6, the input sensing layer TU may include first sensing electrodes IE1-1 to IE1-5, first signal lines SL1-1 to SL1-5 connected to the first sensing electrodes IE1-1 to IE1-5, second sensing electrodes IE2-1 to IE2-4, and second signal lines SL2-1 to SL2-4 connected to the second sensing electrodes IE2-1 to IE2-4. According to some embodiments, the input sensing layer TU may further include an optical dummy electrode arranged in a boundary area between the first sensing electrodes IE1-1 to IE1-5 and the second sensing electrodes IE2-1 to IE2-4.

The thin film encapsulation layer TFE shown in FIG. 3A includes at least one organic encapsulation layer 320 (refer to FIG. 8) and thus provides a more planarized base surface. Accordingly, even when the above elements of the input sensing layer TU are formed through successive processes, a defect rate may be reduced. The first signal lines SL1-1 to SL1-5 and the second signal lines SL2-1 to SL2-4 may be arranged in the peripheral area NDA with a reduced step difference to have a uniform thickness. Thus, for the first signal lines SL1-1 to SL1-5 and the second signal lines SL2-1 to SL2-4, stress due to the step difference of a lower layer thereof may be reduced.

The first sensing electrodes IE1-1 to IE1-5 and the second sensing electrodes IE2-1 to IE2-4 cross each other. The first sensing electrodes IE1-1 to IE1-5 may be lined up in a second direction (e.g., a direction y), and each of the first sensing electrodes IE1-1 to IE1-5 may extend in a first direction (e.g., a direction x). The second sensing electrodes IE2-1 to IE2-4 may be lined up in the first direction (e.g., the direction x), and each of the second sensing electrodes IE2-1 to IE2-4 may extend in the second direction (e.g., the direction y).

Each of the first sensing electrodes IE1-1 to IE1-5 includes first sensor portions SP1 and first connection portions CP1. Each of the second sensing electrodes IE2-1 to IE2-4 includes second sensor portions SP2 and second connection portions CP2. Among the first sensor portions SP1, two first sensor portions arranged at both ends of a first sensing electrode may have a size that is smaller than that of a first sensor portion arranged in the center, for example, half a size of a first sensor portion arranged in the center. Among the second sensor portions SP2, two second sensor portions arranged at both ends of a second sensing electrode may have a size that is smaller than that of a second sensor portion arranged in the center, for example, half a size of a second sensor portion arranged in the center.

Although FIG. 6 shows the first sensing electrodes IE1-1 to IE1-5 and the second sensing electrodes IE2-1 to IE2-4 according to some embodiments, shapes thereof are not limited thereto. According to some embodiments, the first sensing electrodes IE1-1 to IE1-5 and the second sensing electrodes IE2-1 to IE2-4 may have a shape (e.g., a bar shape) in which there is no distinction between a sensor portion and a connection portion. Although the first sensor portions SP1 and the second sensor portions SP2 having a rhombus shape are shown as an example, one or more embodiments are not limited thereto, and the first sensor portions SP1 and the second sensor portions SP2 may have another polygonal shape.

Within one first sensing electrode, the first sensor portions SP1 are lined up in the first direction (e.g., the direction x), and within one second sensing electrode, the second sensor portions SP2 are lined up in the second direction (e.g., the direction y). Each of the first connection portions CP1 connects adjacent first sensor portions SP1 to each other, and each of the second connection portions CP2 connects adjacent second sensor portions SP2 to each other.

The first signal lines SL1-1 to SL1-5 are connected to one end of the first sensing electrodes IE1-1 to IE1-5, respectively. The second signal lines SL2-1 to SL2-4 are connected to both ends of the second sensing electrodes IE2-1 to IE2-4. According to some embodiments, the first signal lines SL1-1 to SL1-5 may also be connected to both ends of the first sensing electrodes IE1-1 to IE1-5. According to some embodiments, the second signal lines SL2-1 to SL2-4 may be connected to only one end of the second sensing electrodes IE2-1 to IE2-4, respectively.

The first signal lines SL1-1 to SL1-5 and the second signal lines SL2-1 to SL2-4 may be connected to a pad portion PD positioned at one side. The pad portion PD may be aligned with a pad area PDA.

According to some embodiments, positions of the first signal lines SL1-1 to SL1-5 and the second signal lines SL2-1 to SL2-4 may be reversed. Unlike that shown in FIG. 6, the first signal lines SL1-1 to SL1-5 may be arranged on the left, and the second signal lines SL2-1 to SL2-4 may be arranged on the right.

Referring to FIG. 6, according to some embodiments, the first sensing electrodes IE1-1 to IE1-5 and the second sensing electrodes IE2-1 to IE2-4 may have a mesh shape. Because the first sensing electrodes IE1-1 to IE1-5 and the second sensing electrodes IE2-1 to IE2-4 have a mesh shape, parasitic capacitance with electrodes (e.g., an opposite electrode) of the display layer DU (of FIG. 2) may be reduced. In addition, as will be described below, the first sensing electrodes IE1-1 to IE1-5 and the second sensing electrodes IE2-1 to IE2-4 do not overlap an emission area and thus are not visible to a user of the display apparatus 1.

The first sensing electrodes IE1-1 to IE1-5 and the second sensing electrodes IE2-1 to IE2-4 having a mesh shape may be formed of metal capable of low-temperature processing, and for example, may include silver, aluminum, copper, chromium, nickel, titanium, etc. Accordingly, even when the input sensing layer TU is formed through successive processes, damage to a light-emitting element may be prevented or reduced.

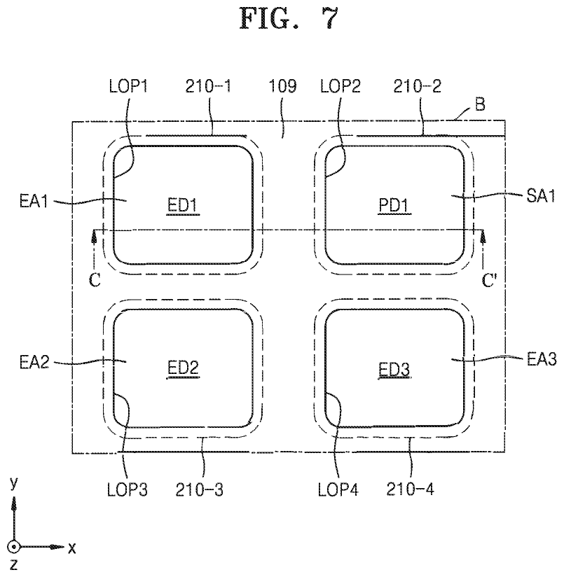

FIG. 7 is a schematic plan view of a portion of a display apparatus according to some embodiments, and is an enlarged schematic plan view of a region B of FIG. 1. In FIG. 7, a plan view over a bank layer 109 is illustrated for convenience.

Referring to FIG. 7, the display apparatus 1 may include a plurality of light-emitting elements and a plurality of light-receiving elements. The plurality of light-emitting elements may include the first light-emitting element ED1, the second light-emitting element ED2, and the third light-emitting element ED3. The plurality of light-receiving elements may include the first light-receiving element PD1 and may further include light-receiving elements. The first light-emitting element ED1, the second light-emitting element ED2, and the third light-emitting element ED3 may emit light of different colors from one another. For example, the first light-emitting element ED1 may emit green light, the second light-emitting element ED2 may emit red light, and the third light-emitting element ED3 may emit blue light. The red light may be light in a wavelength band of 580 nm to 780 nm, the blue light may be light in a wavelength band of 380 nm to 495 nm, and the green light may be light in a wavelength band of 495 nm to 580 nm. The first light-receiving element PD1 may sense an object by detecting light emitted from the first light-emitting element ED1, the second light-emitting element ED2, and the third light-emitting element ED3 and reflected by the object. According to some embodiments, the first light-receiving element PD1 may detect light in a wavelength band of 495 nm to 580 nm, emitted from the first light-emitting element ED1 and reflected by an object.

Each light-emitting element may include a pixel electrode, an opposite electrode, and an intermediate layer located therebetween, and the light-receiving element may include a sensing electrode, an opposite electrode, and an intermediate layer located therebetween. Accordingly, the first light-emitting element ED1 may include a first pixel electrode 210-1, the second light-emitting element ED2 may include a second pixel electrode 210-3, the third light-emitting element ED3 may include a third pixel electrode 210-4, and the first light-receiving element PD1 may include a first sensing electrode 210-2. The first pixel electrode 210-1, the second pixel electrode 210-3, the third pixel electrode 210-4, and the first sensing electrode 210-2 may be apart from one another over the substrate 100 (refer to FIG. 8). As used herein, the phrase “in a plan view” refers to a plan view taken in a direction perpendicular to the substrate 100. That is, the description “A and B apart from each other in a plan view” refers to “A and B apart from each other when viewed in a direction perpendicular to the substrate 100” (e.g., in a plan view).

The bank layer 109 may be located on the first pixel electrode 210-1, the second pixel electrode 210-3, the third pixel electrode 210-4, and the first sensing electrode 210-2, and may cover the edge of each of the first pixel electrode 210-1, the second pixel electrode 210-3, the third pixel electrode 210-4, and the first sensing electrode 210-2. That is, the bank layer 109 may have a first bank layer opening LOP1 exposing a central portion of the first pixel electrode 210-1, a second bank layer opening LOP2 exposing a central portion of the first sensing electrode 210-2, a third bank layer opening LOP3 exposing a central portion of the second pixel electrode 210-3, and a fourth bank layer opening LOP4 exposing a central portion of the third pixel electrode 210-4.

According to some embodiments, emission layers for emitting light may be positioned in the first bank layer opening LOP1, the third bank layer opening LOP3, and the fourth bank layer opening LOP4 of the bank layer 109, respectively, and an active layer for detecting light may be positioned in the second bank layer opening LOP2 of the bank layer 109. The opposite electrode may be located over the emission layers and the active layer. As described above, a stacked structure of a pixel electrode, an emission layer, and an opposite electrode may constitute one light-emitting element. In addition, as described above, a stacked structure of a sensing electrode, an active layer, and an opposite electrode may constitute one light-receiving element. One opening in the bank layer 109 may correspond to one light-emitting element and may define one emission area. Alternatively, one opening in the bank layer 109 may correspond to one light-receiving element and may define one sensing area.

For example, an emission layer for emitting green light may be arranged in the first bank layer opening LOP1, and thus, the first bank layer opening LOP1 may define a first emission area EA1. Similarly, an emission layer for emitting red light may be arranged in the third bank layer opening LOP3, and thus, the third bank layer opening LOP3 may define a second emission area EA2. An emission layer for emitting blue light may be arranged in the fourth bank layer opening LOP4, and thus, the fourth bank layer opening LOP4 may define a third emission area EA3. An active layer for detecting light may be arranged in the second bank layer opening LOP2, and thus, the second bank layer opening LOP2 may define a first sensing area SA1.

Accordingly, an area of the first bank layer opening LOP1 is equal to that of the first emission area EA1. An area of the second bank layer opening LOP2 is equal to that of the first sensing area SA1, and an area of the third bank layer opening LOP3 is equal to that of the second emission area EA2. An area of the fourth bank layer opening LOP4 is equal to that of the third emission area EA3.

Each of the first bank layer opening LOP1, the second bank layer opening LOP2, the third bank layer opening LOP3, and the fourth bank layer opening LOP4 may have a polygonal shape when viewed in a direction (a z-axis direction) perpendicular to the substrate 100 (of FIG. 8) (e.g., in a plan view). In other words, each of the first emission area EA1, the second emission area EA2, the third emission area EA3, and the first sensing area SA1 may have a polygonal shape when viewed in a direction (the z-axis direction) perpendicular to the substrate 100 (e.g., in a plan view). In FIG. 7, each of the first emission area EA1, the second emission area EA2, the third emission area EA3, and the first sensing area SA1 is shown as having a quadrilateral shape, for example, a quadrilateral shape with round corners, when viewed in a direction (the z-axis direction) perpendicular to the substrate 100 (e.g., in a plan view). However, embodiments according to the present disclosure are not limited thereto. For example, each of the first emission area EA1, the second emission area EA2, the third emission area EA3, and the first sensing area SA1 may have a circular shape or an oval shape when viewed in a direction (the z-axis direction) perpendicular to the substrate 100 (e.g., in a plan view).

FIG. 8 is a schematic cross-sectional view of a portion of the display apparatus 1 according to some embodiments, taken along a line C-C′ of FIG. 7.

Referring to FIG. 8, the display apparatus 1 may include the substrate 100, a thin-film transistor TFT, the first light-emitting element ED1, the first light-receiving element PD1, the thin film encapsulation layer TFE, the input sensing layer TU, the color filter member CU, and the cover window CW.

The substrate 100 may include glass or polymer resin. The substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 including polymer resin may be flexible, rollable, or bendable. The substrate 100 may have a multi-layer structure including a layer including the above polymer resin and an inorganic layer.

A buffer layer 101 may be positioned on the substrate 100 to decrease or prevent penetration of a foreign material, moisture, or external air from below the substrate 100 and may provide a flat surface on the substrate 100. The buffer layer 101 may include an inorganic material, such as oxide or nitride, an organic material, or an organic-inorganic compound, and may have a single-layer or multi-layer structure including an inorganic material and an organic material. According to some embodiments, the buffer layer 101 may include silicon oxide (SiOX), silicon nitride (SiNX) and/or silicon oxynitride (SiON).

The thin-film transistor TFT may be located on the buffer layer 101. The thin-film transistor TFT may include a semiconductor layer Act, a gate electrode GE, a source electrode SE, and a drain electrode DE. Although FIG. 8 shows a top gate type in which the gate electrode GE is arranged over the semiconductor layer Act with a gate insulating layer 203 therebetween, one or more embodiments are not limited thereto. For example, the thin-film transistor TFT may be of a bottom gate type.

The semiconductor layer Act may be on the buffer layer 101. The semiconductor layer Act may include a channel region, and source and drain regions arranged at both sides of the channel region and doped with impurities. In this regard, the impurities may include N-type impurities or P-type impurities. The semiconductor layer Act may include amorphous silicon or polysilicon. According to some embodiments, the semiconductor layer Act may include oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In addition, the semiconductor layer Act may include a Zn oxide-based material, such as Zn oxide, In—Zn oxide, Ga—In—Zn oxide, etc. In addition, the semiconductor layer Act may be an In—Ga—Zn—O(IGZO), In—Sn—Zn—O(ITZO), or In—Ga—Sn—Zn—O(IGTZO) semiconductor containing metal, such as indium (In), gallium (Ga), and stannum (Sn), in ZnO.

The gate electrode GE may be arranged over the semiconductor layer Act to at least partially overlap the semiconductor layer Act. For example, the gate electrode GE may overlap the channel region of the semiconductor layer Act. The gate electrode GE may include various conductive materials including molybdenum (Mo), aluminum (Al), copper (Cu), titanium (Ti), etc., and may have various layer structures. For example, the gate electrode GE may include a Mo layer and an Al layer or may have a multi-layer structure of Mo layer/Al layer/Mo layer.

A gate insulating layer 103 may be located between the semiconductor layer Act and the gate electrode GE. The gate insulating layer 103 may include silicon oxide (SiOₓ), silicon nitride (SiNₓ) and/or silicon oxynitride (SiON) and may have a single-layer or multi-layer structure.

The source electrode SE and the drain electrode DE may be connected to the source region and the drain region of the semiconductor layer Act through contact holes. The source electrode SE and the drain electrode DE may include various conductive materials including molybdenum (Mo), aluminum (Al), copper (Cu), titanium (Ti), etc., and may have various layer structures. For example, the source electrode SE and the drain electrode DE may include a Ti layer and an Al layer or may have a multi-layer structure of Ti layer/Al layer/Ti layer. In addition, the source electrode SE and the drain electrode DE may have a multi-layer structure including an ITO layer covering a metal material.

An interlayer insulating layer 105 may be located between the gate electrode GE and the source electrode SE and between the gate electrode GE and the drain electrode DE. The interlayer insulating layer 105 may include silicon oxide (SiOₓ), silicon nitride (SiNₓ) and/or silicon oxynitride (SiON) and may have a single-layer or multi-layer structure.

The thin-film transistor TFT may be covered by an organic insulating layer 107. For example, the organic insulating layer 107 may cover the source electrode SE and the drain electrode DE. The organic insulating layer 107, which is a planarization insulating layer, may have an upper surface that is substantially flat. The organic insulating layer 107 may include an organic insulating material, such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof. According to some embodiments, the organic insulating layer 107 may include polyimide.

The first pixel electrode 210-1, the first sensing electrode 210-2, and the bank layer 109 may be located on the organic insulating layer 107. The bank layer 109 may be located on the organic insulating layer 107 while covering the edge of the first pixel electrode 210-1 and the first sensing electrode 210-2.

The first bank layer opening LOP1 exposing at least a central portion of the first pixel electrode 210-1 and the second bank layer opening LOP2 exposing at least a central portion of the first sensing electrode 210-2 may be arranged in the bank layer 109. Accordingly, the first bank layer opening LOP1 may define the first emission area EA1, and the second bank layer opening LOP2 may define the first sensing area SA1.

The bank layer 109 may prevent or reduce an arc, etc., from occurring at the edge of first pixel electrodes 210-1 by increasing a distance between the edge of the first pixel electrode 210-1 and an opposite electrode 230. In addition, the bank layer 109 may prevent or reduce an arc, etc., from occurring at the edge of first sensing electrodes 210-2 by increasing a distance between the edge of the first sensing electrode 210-2 and the opposite electrode 230.

The bank layer 109 may include an organic insulating material, such as polyimide, polyamide, acrylic resin, benzocyclobutene, hexamethyldisiloxane (HMDSO), and phenolic resin, and may be formed by a method such as spin coating.

An emission layer 222-1 may be arranged in the first bank layer opening LOP1 arranged in the bank layer 109. The emission layer 222-1 may include an organic material including a fluorescent or phosphorescent material that emits red, green, blue, or white light. The emission layer 222-1 may be an organic emission layer including a low-molecular weight organic material or a polymer organic material. For example, the emission layer 222-1, which is an organic emission layer, may include copper phthalocyanine, tris-8-hydroxyquinoline aluminum, a polyphenylene vinylene (PPV)-based material, or a polyfluorene-based material.

According to some embodiments, the emission layer 222-1 may include a host material and a dopant material. The dopant material, which is a material that emits light of a certain color, may include a light-emitting material. The light-emitting material may include at least one of a phosphorescent dopant, a fluorescent dopant, or a quantum dot. The host material, which is a main material of the emission layer 222-1, helps the dopant material to emit light.

An active layer 222-2 may be arranged in the second bank layer opening LOP2 arranged in the bank layer 109. The active layer 222-2 may include a p-type organic semiconductor and an n-type organic semiconductor. In this regard, the p-type organic semiconductor may serve as an electron donor, and the n-type organic semiconductor may serve as an electron acceptor.

According to some embodiments, the active layer 222-2 may be a mixed layer of the p-type organic semiconductor and the n-type organic semiconductor. In this case, the active layer 222-2 may be formed by co-depositing the p-type organic semiconductor and the n-type organic semiconductor. When the active layer 222-2 is a mixed layer, excitons may be generated within a diffusion length from a donor-acceptor interface.

According to some embodiments, the p-type organic semiconductor may be a compound that serves as an electron donor for supplying electrons. For example, the p-type organic semiconductor may include boron subphthalocyanine chloride (SubPc), copper (II) phthalocyanine (CuPc), tetraphenyl dibenzoperiplantene (DBP), or any combination thereof, but one or more embodiments are not limited thereto.

According to some embodiments, the n-type organic semiconductor may be a compound that serves as an electron acceptor for accepting electrons. For example, the n-type organic semiconductor may include C60 fullerene, C70 fullerene, or any combination thereof, but one or more embodiments are not limited thereto.

The opposite electrode 230 may be arranged over the emission layer 222-1 and the active layer 222-2. The opposite electrode 230 arranged over the emission layer 222-1 and the active layer 222-2 may be integrally formed. The opposite electrode 230 may be a transmissive electrode or a reflective electrode. According to some embodiments, the opposite electrode 230 may be a transparent or semitransparent electrode and may include a metal thin film with a low work function including Li, Ca, LiF/Ca, LiF/Al, Al, Ag, Mg, and a compound thereof. The opposite electrode 230 may further include a transparent conductive oxide (TCO) film, such as ITO, IZO, ZnO, or In2O3, in addition to the metal thin film.

A first common layer 221 may be located between the first pixel electrode 210-1 and the emission layer 222-1 and between the first sensing electrode 210-2 and the active layer 222-2, and a second common layer 223 may be located between the emission layer 222-1 and the opposite electrode 230 and between the active layer 222-2 and the opposite electrode 230.

According to some embodiments, a hole transport region may be defined between the first pixel electrode 210-1 and the emission layer 222-1 and between the first sensing electrode 210-2 and the active layer 222-2, and an electron transport region may be defined between the emission layer 222-1 and the opposite electrode 230 and between the active layer 222-2 and the opposite electrode 230.

The hole transport region may have a single-layer structure or a multi-layer structure. For example, the first common layer 221 may be arranged in the hole transport region. According to some embodiments, the first common layer 221 may include at least one of a hole injection layer (HIL), a hole transport layer (HTL), or an electron blocking layer (EBL).

For example, the first common layer 221 may have a single-layer structure or a multi-layer structure. When the first common layer 221 has a multi-layer structure, the first common layer 221 may include an HIL and an HTL, an HIL and an EBL, an HTL and an EBL, or an HIL, an HTL, and an EBL, which are sequentially stacked on the first pixel electrode 210-1. However, embodiments according to the present disclosure are not limited thereto.

According to some embodiments, the first common layer 221 may include at least one selected from among m-MTDATA, TDATA, 2-TNATA, NPB(NPD), β-NPB, TPD, Spiro-TPD, Spiro-NPB, methylated-NPB, TAPC, HMTPD, 4,4′,4-tris(N-carbazolyl)triphenylamine (TCTA), polyaniline/dodecylbenzenesulfonic acid (Pani/DBSA), polyaniline/camphor sulfonic acid (Pani/CSA), poly(3,4-ethylenedioxythiophene)/poly(4-styrenesulfonate) (PEDOT/PSS), and polyaniline/poly(4-styrenesulfonate) (PANI/PSS).

The electron transport region may have a single-layer structure or a multi-layer structure. For example, the second common layer 223 may be arranged in the electron transport region. According to some embodiments, the second common layer 223 may include at least one of an electron injection layer (EIL), an electron transport layer (ETL), or a hole blocking layer (HBL).

For example, the second common layer 223 may have a single-layer structure or a multi-layer structure. When the second common layer 223 has a multi-layer structure, the second common layer 223 may include an ETL and an EIL, an HBL and an EIL, an HBL and an ETL, or an HBL, an ETL, and an EIL, which are sequentially stacked on the emission layer 222-1. However, one or more embodiments are not limited thereto.

According to some embodiments, the second common layer 223 may include at least one compound selected from among 2,9-Dimethyl-4,7-diphenyl-1,10-phenanthroline (BCP), 4,7-Diphenyl-1,10-phenanthroline (Bphen), Alq3, BAlq, 3-(Biphenyl-4-yl)-5-(4-tert-butylphenyl)-4-phenyl-4H-1,2,4-triazole (TAZ), and NTAZ.

The first light-emitting element ED1 may include the first pixel electrode 210-1, the first common layer 221, the emission layer 222-1, the second common layer 223, and the opposite electrode 230 that are sequentially stacked. The first light-receiving element PD1 may include the first sensing electrode 210-2, the first common layer 221, the active layer 222-2, the second common layer 223, and the opposite electrode 230 that are sequentially stacked.

The thin-film transistor TFT may be located between the substrate 100 and the first light-emitting element ED1. The thin-film transistor TFT may be electrically connected to the first light-emitting element ED1 to drive the first light-emitting element ED1. For example, one of the source electrode SE and the drain electrode DE of the thin-film transistor TFT may be electrically connected to the first pixel electrode 210-1 of the first light-emitting element ED1.

The thin-film transistor TFT may be located between the substrate 100 and the first light-receiving element PD1. The thin-film transistor TFT may be electrically connected to the first light-receiving element PD1 to drive the first light-receiving element PD1. For example, one of the source electrode SE and the drain electrode DE of the thin-film transistor TFT may be electrically connected to the first sensing electrode 210-2 of the first light-receiving element PD1.

The active layer 222-2 may receive light from the outside and generate excitons and then may separate the generated excitons into holes and electrons. When a (+) electric potential is applied to the first sensing electrode 210-2, and a (−) electric potential is applied to the opposite electrode 230, the holes separated in the active layer 222-2 may move toward the opposite electrode 230, and the electrons separated in the active layer 222-2 may move toward the first sensing electrode 210-2. Accordingly, a photocurrent may be formed in a direction from the first sensing electrode 210-2 to the opposite electrode 230.

When a bias is applied between the first sensing electrode 210-2 and the opposite electrode 230, a dark current may flow in the first light-receiving element PD1. In addition, when light is incident on the first light-receiving element PD1, a photocurrent may flow in the first light-receiving element PD1. According to some embodiments, the first light-receiving element PD1 may detect an amount of light from a ratio of the photocurrent and the dark current.

An auxiliary layer 240 may be located on the first light-emitting element ED1 and the first light-receiving element PD1. For example, the auxiliary layer 240 may be located on the opposite electrode 230. The auxiliary layer 240 may facilitate the movement of holes by lowering an energy barrier of holes moving toward an HTL and an anode. The auxiliary layer 240 may include, for example, a fluorene-based compound, a carbazole-based compound, a diarylamine-based compound, a triarylamine-based compound, a dibenzofuran-based compound, a dibenzothiophene-based compound, a dibenzosilol-based compound, or any combination thereof.

The thin film encapsulation layer TFE may be arranged over the first light-emitting element ED1 and the first light-receiving element PD1. For example, the thin film encapsulation layer TFE may be located on the auxiliary layer 240. The thin film encapsulation layer TFE may include at least one inorganic encapsulation layer and at least one organic encapsulation layer, and according to some embodiments, FIG. 8 shows the thin film encapsulation layer TFE including a first inorganic encapsulation layer 310, the organic encapsulation layer 320, and a second inorganic encapsulation layer 330 that are sequentially stacked.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include acryl-based resin, epoxy-based resin, polyimide, and polyethylene. According to some embodiments, the organic encapsulation layer 320 may include acrylate. The organic encapsulation layer 320 may be formed by curing a monomer or applying a polymer. The organic encapsulation layer 320 may have transparency.

The input sensing layer TU may be located on the thin film encapsulation layer TFE. The input sensing layer TU may obtain coordinate information according to an external input, for example, a touch event. The input sensing layer TU may include the first conductive layer MTL1, the first inorganic insulating layer IL1 on the first conductive layer MTL1, the second conductive layer MTL2 on the first inorganic insulating layer IL1, and the second inorganic insulating layer IL2 on the second conductive layer MTL2. The first conductive layer MTL1 and the second conductive layer MTL2 may correspond to the first sensor portion SP1 of FIG. 6. According to some embodiments, an insulating layer may be additionally located between the first conductive layer MTL1 and the thin film encapsulation layer TFE.

As described above, the first sensor portions SP1 may not overlap an emission area and may overlap a non-emission area. The first conductive layer MTL1 and the second conductive layer MTL2 may not overlap the first emission area EA1 and/or the first sensing area SA1. That is, the first conductive layer MTL1 and the second conductive layer MTL2 may overlap the bank layer 109 and/or the light-blocking layer BM. According to some embodiments, in some areas, the first conductive layer MTL1 and the second conductive layer MTL2 may be electrically connected to each other through a contact hole defined in the second inorganic insulating layer IL2.

The color filter member CU may be located on the input sensing layer TU. The color filter member CU may include the light-blocking layer BM, the color filter layer CF, and an overcoat layer OC.

The light-blocking layer BM may be located on the input sensing layer TU. Because the light-blocking layer BM includes a light-blocking material, the light-blocking layer BM may at least partially absorb internally reflected light. The light-blocking material may include carbon black, carbon nanotubes, resin or paste including black dye, or metal particles. The metal particles may be, for example, nickel, aluminum, molybdenum and/or an alloy thereof. In addition, the light-blocking material may include metal oxide particles such as chromium oxide, or metal nitride particles such as chromium nitride. Because the light-blocking layer BM includes a light-blocking material, the light-blocking layer BM may reduce external light reflection. In some cases, the light-blocking layer BM may include the same material as the bank layer 109 below. However, one or more embodiments are not limited thereto, and the light-blocking layer BM may include a material different from that of the bank layer 109.

The light-blocking layer BM may include a first light-blocking layer opening UOP1 corresponding to the first emission area EA1 and a second light-blocking layer opening UOP2 corresponding to the first sensing area SA1. That is, the first light-blocking layer opening UOP1 may overlap the first bank layer opening LOP1, and the second light-blocking layer opening UOP2 may overlap the second bank layer opening LOP2. An area of the first light-blocking layer opening UOP1 may be greater than that of the first bank layer opening LOP1, and an area of the second light-blocking layer opening UOP2 may be greater than that of the second bank layer opening LOP2. The light-blocking layer BM may include a plurality of light-blocking layer openings UOP1 and UOP2 and thus may have a grid shape or a mesh shape. In addition, shapes of the first light-blocking layer opening UOP1 and the second light-blocking layer opening UOP2 of the light-blocking layer BM may be respectively the same as those of the first bank layer opening LOP1 and the second bank layer opening LOP2 of the bank layer 109.

The color filter layer CF may be located on the light-blocking layer BM, and the color filter layer CF may include a first color filter CF1 and a second color filter CF2. The first color filter CF1 and the second color filter CF2 may transmit only light having a wavelength in a certain band. The first color filter CF1 may fill the first light-blocking layer opening UOP1 of the light-blocking layer BM, and the second color filter CF2 may fill the second light-blocking layer opening UOP2 of the light-blocking layer BM.

In the display apparatus 1, the color filter layer CF is arranged over each pixel to reduce external light reflection. For example, in the case of a pixel that emits red light, a red color filter for transmitting only red light may be arranged over the pixel, and in the case of a pixel that emits blue light, a blue color filter for transmitting only blue light may be arranged over the pixel. Thus, when external light, which is white light, is incident on, for example, the red color filter, blue light and green light are absorbed by the red color filter, and only red light passes through the red color filter and then is reflected from a pixel electrode, passes through the red color filter again, and is emitted to the outside. Accordingly, in the case of a display apparatus with a color filter, external light reflection is reduced to approximately ⅓ compared to the case without a color filter.

The first color filter CF1 may transmit light emitted from the first light-emitting element ED1. For example, when the first light-emitting element ED1 emits green light, the first color filter CF1 may be a green color filter that transmits green light. In addition, when the first light-emitting element ED1 emits red light, the first color filter CF1 may be a red color filter that transmits red light.

The second color filter CF2 may transmit light of the same color as the first color filter CF1. When the first color filter CF1 is a green color filter, the second color filter CF2 may be a green color filter. In addition, when the first color filter CF1 is a red color filter, the second color filter CF2 may be a red color filter. That is, according to some embodiments, the first color filter CF1 and the second color filter CF2 may be green color filters that transmit light in a wavelength band of 495 nm to 580 nm.

In this regard, the second color filter CF2 arranged over the first light-receiving element PD1 and overlapping the first sensing area SA1 may include a convex upper surface. That is, the second color filter CF2 may be a convex light-transmitting portion CP having a convex lens shape. In other words, the convex light-transmitting portion CP may include the same material as at least one of the color filters that transmit light of different colors from one another.

For example, the convex light-transmitting portion CP may have a lower surface facing the substrate 100 and an upper surface facing an opposite side of the substrate 100, and the upper surface of the convex light-transmitting portion CP may include a convex surface protruding beyond the light-blocking layer BM. In other words, based on a thickness direction of the substrate 100, a cross-section of the convex light-transmitting portion CP may have a shape that becomes thicker toward a center of the convex light-transmitting portion CP, and accordingly, a thickness H2 of a central portion of the convex light-transmitting portion CP may be greater than a thickness H1 of the light-blocking layer BM. When the convex light-transmitting portion CP described above has a higher refractive index than the surrounding organic material, the convex light-transmitting portion CP may substantially serve as a convex lens. According to some embodiments, a refractive index of the second color filter CF2 may be higher than that of the overcoat layer OC described below by about 0.1 to about 0.3.

Because the convex light-transmitting portion CP arranged over the first light-receiving element PD1 has a convex upper surface, light that is reflected by an object and incident on the display apparatus 1 again may be refracted at the upper surface of the convex light-transmitting portion CP and condensed toward the first light-receiving element PD1. For example, as shown in FIG. 8, light reflected by an object and brought into the display apparatus 1 may include first light L1 and L1′ incident at an angle toward the upper surface of the convex light-transmitting portion CP. The first light L1 and L1′ may be refracted at an interface between the convex light-transmitting portion CP having a convex upper surface and the overcoat layer OC to have a changed path, and the refracted first light L1 and L1′ may be extracted substantially in a third direction (a direction z) and brought into the first light-receiving element PD1 as second light L2 and L2′.

In addition, a capturing area, which is an area capable of light receiving into the first light-receiving element PD1, may be reduced according to a refraction phenomenon of light incident on the convex light-transmitting portion CP described above. A plurality of light-receiving elements may each have a capturing area and may sense a fingerprint by detecting light brought therein from the corresponding area. In this regard, when the capturing area of a light-receiving element excessively widens, capturing areas of adjacent light-receiving elements may overlap each other. When the capturing areas of light-receiving elements overlap each other, a ridge signal and a valley signal of a target fingerprint may be mixed with each other to degrade sensor performance of the light-receiving element and cause an image blurring problem. On the other hand, in the display apparatus 1 shown in FIG. 8, light brought therein may be condensed by the convex light-transmitting portion CP with a convex lens shape to reduce a capturing area, and accordingly, the overlap problem may not occur between capturing areas of light-receiving elements adjacent to each other. Particularly, the convex light-transmitting portion CP may be filled in the second light-blocking layer opening UOP2, and accordingly, the size of a capturing area may be adjusted by adjusting an opening in the light-blocking layer BM. As a result, in the display apparatus 1 according to some embodiments, the convex light-transmitting portion CP may be arranged over the first light-receiving element PD1 to reduce a capturing area and also increase light-receiving efficiency, thereby relatively improving photodetectivity of the first light-receiving element PD1 and preventing or reducing defects such as image blurring.

The first color filter CF1 arranged over the first light-emitting element ED1 is shown in FIG. 8 as having a flat upper surface. However, in some embodiments, like the second color filter CF2, the first color filter CF1 may also have a convex upper surface.

The color filter member CU may further include the overcoat layer OC. The overcoat layer OC may cover the light-blocking layer BM and the color filter layer CF. The overcoat layer OC may be integrally formed over the first emission area EA1 and the first sensing area SA1. The overcoat layer OC, which is a colorless transmissive layer that does not have any color of the visible band, may planarize an upper surface of the color filter member CU including the color filter layer CF. For example, the overcoat layer OC may include an organic material, such as acryl, benzocyclobutene (BCB), or hexamethyldisiloxane (HMDSO).

The cover window CW may be arranged over the color filter member CU. The cover window CW may include at least one of glass, sapphire, and plastic. The cover window CW may be, for example, Ultra-Thin Glass (UTG) or Colorless Polyimide (CPI).

The adhesive member AD may be located between the cover window CW and the color filter member CU. Accordingly, the adhesive member AD may couple the cover window CW and the color filter member CU to each other. As the adhesive member AD, a general one known in the art may be employed without limitation. For example, the adhesive member AD may be an optical clear adhesive (OCA) or a pressure sensitive adhesive (PSA).

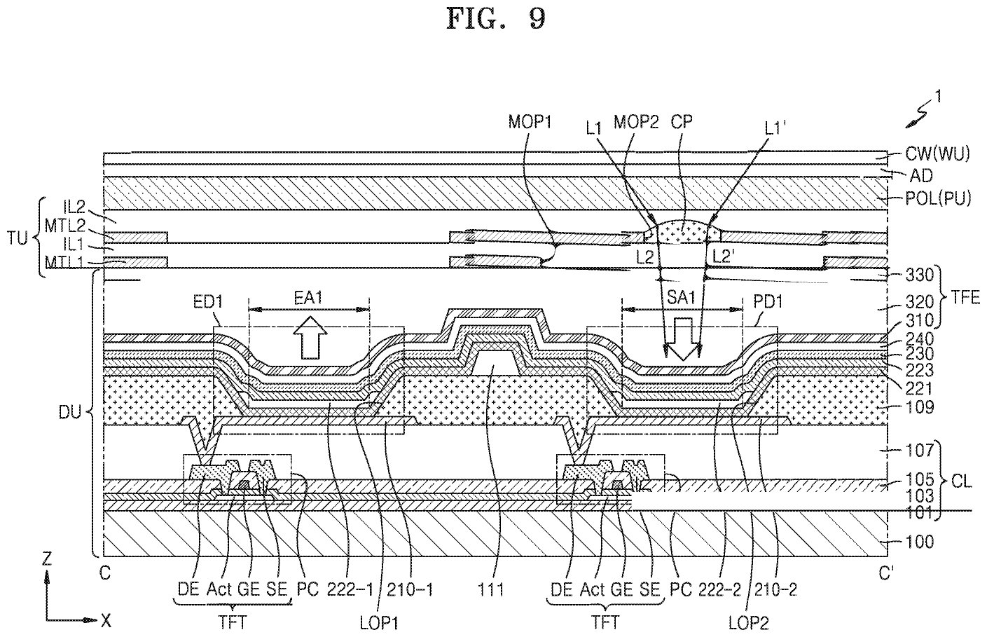

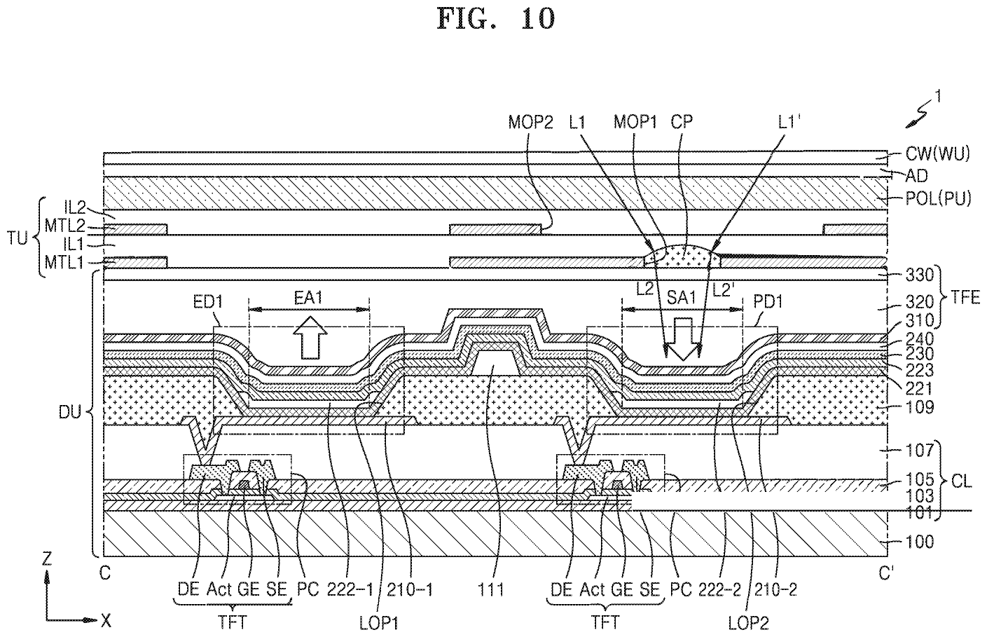

FIG. 9 is a schematic cross-sectional view of a portion of the display apparatus 1 according to some embodiments. FIG. 10 is a schematic cross-sectional view of a portion of the display apparatus 1 according to some embodiments. Referring to FIGS. 9 and 10, except for features of the input sensing layer TU, the convex light-transmitting portion CP, and the polarizing member PU, other features are the same as those described with reference to FIGS. 7 and 8. Among the elements of FIGS. 9 and 10, the same reference numerals are replaced with those described above with reference to FIGS. 7 and 8, and differences are mainly described below.

First, referring to FIG. 9, the display apparatus 1 may include the substrate 100, the thin-film transistor TFT, the first light-emitting element ED1, the first light-receiving element PD1, the thin film encapsulation layer TFE, the input sensing layer TU, the polarizing member PU, and the cover window CW.

The polarizing member PU may be located between the input sensing layer TU and the cover window CW instead of the color filter member CU of FIG. 8. The polarizing member PU includes the polarizing layer POL, and as described above, the polarizing layer POL may include a linear polarizer and a phase retarder. The polarizing layer POL may include a phase retarder and thus may change the phase of light. For example, the polarizing layer POL may change light vibrating up and down or light vibrating left and right into right-circularly polarized light or left-circularly polarized light and may change right-circularly polarized light or left-circularly polarized light into light vibrating up and down or light vibrating left and right. In addition, the polarizing layer POL may include a linear polarizer and thus may selectively transmit light. For example, the polarizing layer POL may transmit light vibrating up and down or light vibrating left and right. Thus, the polarizing layer POL may serve as an anti-reflection layer which reduces external light reflection to increase a contrast ratio and visibility.

The input sensing layer TU may include the first conductive layer MTL1, the first inorganic insulating layer IL1 on the first conductive layer MTL1, the second conductive layer MTL2 on the first inorganic insulating layer IL1, and the second inorganic insulating layer IL2 on the second conductive layer MTL2. The first conductive layer MTL1 and the second conductive layer MTL2 may correspond to the first sensor portion SP1 of FIG. 6. As described above, the first sensor portions SP1 may not overlap an emission area and may overlap a non-emission area. The first conductive layer MTL1 and the second conductive layer MTL2 may not overlap the first emission area EA1 and/or the first sensing area SA1. That is, the first conductive layer MTL1 and the second conductive layer MTL2 may overlap the bank layer 109 and/or the light-blocking layer BM.

In other words, the first conductive layer MTL1 and the second conductive layer MTL2 may have openings overlapping the first emission area EA1 and the first sensing area SA1. For example, the first conductive layer MTL1 may include an opening corresponding to the first emission area EA1 and a first conductive layer opening MOP1 corresponding to the first sensing area SA1. The second conductive layer MTL2 may include an opening corresponding to the first emission area EA1 and a second conductive layer opening MOP2 corresponding to the first sensing area SA1. That is, each of the first conductive layer opening MOP1 and the second conductive layer opening MOP2 may overlap the second bank layer opening LOP2.

In the display apparatus 1 shown in FIGS. 9 and 10, by arranging the polarizing member PU instead of the color filter member CU (of FIG. 8), the convex light-transmitting portion CP may be arranged in the first conductive layer opening MOP1 or the second conductive layer opening MOP2.

Referring to FIG. 9, in some embodiments, an area of the second conductive layer opening MOP2 may be less than that of the first conductive layer opening MOP1. That is, the second conductive layer MTL2 of the input sensing layer TU may protrude more toward the first sensing area SA1 than the first conductive layer MTL1. In other words, a portion of the second conductive layer MTL2 may protrude beyond the bank layer 109, and thus, an area of the second conductive layer opening MOP2 may be less than that of the second bank layer opening LOP2. In the display apparatus 1 shown in FIG. 9, the convex light-transmitting portion CP may be arranged in the second conductive layer opening MOP2, and the second inorganic insulating layer IL2 may cover the convex light-transmitting portion CP.

Next, referring to FIG. 10, according to some embodiments, an area of the first conductive layer opening MOP1 may be less than that of the second conductive layer opening MOP2. That is, the first conductive layer MTL1 of the input sensing layer TU may protrude more toward the first sensing area SA1 than the second conductive layer MTL2. In other words, a portion of the first conductive layer MTL1 may protrude beyond the bank layer 109, and thus, an area of the first conductive layer opening MOP1 may be less than that of the second bank layer opening LOP2. In the display apparatus 1 shown in FIG. 10, the convex light-transmitting portion CP may be arranged in the first conductive layer opening MOP1, and the first inorganic insulating layer IL1 may cover the convex light-transmitting portion CP.

The convex light-transmitting portion CP arranged in the display apparatus 1 of FIGS. 9 and 10 is a colorless transmissive layer that does not have any color of the visible band, and may include the same material as the overcoat layer OC of FIG. 8. For example, the convex light-transmitting portion CP may include an organic material, such as acryl, benzocyclobutene (BCB), or hexamethyldisiloxane (HMDSO).

The convex light-transmitting portion CP may include a convex upper surface. For example, a lower surface of the convex light-transmitting portion CP facing the substrate 100 may be flat, and an upper surface facing an opposite side of the substrate 100 may include a convex surface protruding beyond the second conductive layer MTL2 or the first conductive layer MTL1. In other words, based on a thickness direction of the substrate 100, a cross-section of the convex light-transmitting portion CP may have a shape that becomes thicker toward a center of the convex light-transmitting portion CP, and accordingly, a central portion of the convex light-transmitting portion CP may be thicker than the second conductive layer MTL2 or the first conductive layer MTL1. When the convex light-transmitting portion CP described above has a higher refractive index than the surrounding organic material, the convex light-transmitting portion CP may substantially serve as a convex lens. According to some embodiments, a refractive index of the convex light-transmitting portion CP may be higher than that of each of the first inorganic insulating layer IL1 and the second inorganic insulating layer IL2 by about 0.1 to about 0.3.

Because the convex light-transmitting portion CP arranged over the first light-receiving element PD1 has a convex upper surface, light that is reflected by an object and incident on the display apparatus 1 again may be refracted at the upper surface of the convex light-transmitting portion CP and condensed toward the first light-receiving element PD1. For example, as shown in FIGS. 9 and 10, light reflected by an object and brought into the display apparatus 1 may include first light L1 and L1′ incident at an angle toward the upper surface of the convex light-transmitting portion CP. The first light L1 and L1′ may be refracted at an interface between the convex light-transmitting portion CP and the first inorganic insulating layer IL1 or an interface between the convex light-transmitting portion CP and the second inorganic insulating layer IL2 to have a changed path, and the refracted first light L1 and L1′ may be extracted substantially in a third direction (the direction z) and brought into the first light-receiving element PD1 as second light L2 and L2′.

In addition, a capturing area, which is an area capable of light receiving into the first light-receiving element PD1, may be reduced according to a refraction phenomenon of light incident on the convex light-transmitting portion CP described above. In the display apparatus 1 shown in FIGS. 9 and 10, light may be condensed by the convex light-transmitting portion CP with a convex lens shape to reduce a capturing area, and accordingly, an overlap problem may not occur between capturing areas of light-receiving elements adjacent to each other. Particularly, the convex light-transmitting portion CP may be filled in the first conductive layer opening MOP1 or the second conductive layer opening MOP2, and accordingly, the size of a capturing area may be adjusted by adjusting the first conductive layer opening MOP1 or the second conductive layer opening MOP2. As a result, in the display apparatus 1 according to some embodiments, the convex light-transmitting portion CP may be arranged over the first light-receiving element PD1 to reduce a capturing area and also increase light-receiving efficiency, thereby relatively improving photodetectivity of the first light-receiving element PD1 and preventing or reducing defects such as image blurring.

Although the display apparatus 1 shown in FIGS. 9 and 10 has a structure in which the convex light-transmitting portion CP is arranged in the first conductive layer opening MOP1 or the second conductive layer opening MOP2, one or more embodiments are not limited thereto. That is, the convex light-transmitting portion CP may be arranged in both of the first conductive layer opening MOP1 and the second conductive layer opening MOP2 to adjust a capturing area by using each of the first conductive layer opening MOP1 and the second conductive layer opening MOP2.

In a display apparatus according to one or more of the above embodiments, detectivity of a sensor may be relatively improved by arranging a convex light-transmitting portion over a light-receiving element. However, the above characteristics are merely examples, and embodiments according to the present disclosure are not limited to such characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate having an emission area and a sensing area;
a light-emitting element over the substrate and overlapping the emission area;
a light-receiving element over the substrate and overlapping the sensing area;
an upper layer over the light-emitting element and the light-receiving element and comprising a sensing opening overlapping the light-receiving element; and
a convex light-transmitting portion filling the sensing opening and comprising a convex upper surface.

2. The display apparatus of claim 1, wherein the upper layer is a light-blocking layer comprising a light-blocking material,
wherein the light-blocking layer comprises a first light-blocking layer opening overlapping the light-emitting element and a second light-blocking layer opening overlapping the light-receiving element,
wherein the sensing opening is the second light-blocking layer opening, and the convex light-transmitting portion is in the second light-blocking layer opening.

3. The display apparatus of claim 2, further comprising a color filter layer filling the first light-blocking layer opening,
wherein the color filter layer comprises a first color filter, a second color filter, and a third color filter that are configured to transmit light of different colors from each other.

4. The display apparatus of claim 3, wherein the convex light-transmitting portion comprises a same material as at least one of the first color filter, the second color filter, or the third color filter.

5. The display apparatus of claim 4, wherein the convex light-transmitting portion is configured to transmit light having a wavelength in a range of 495 nanometers (nm) to 580 nm.

6. The display apparatus of claim 3, wherein, based on a thickness direction of the substrate, a cross-section of the convex light-transmitting portion has a shape that becomes thicker toward a center of the convex light-transmitting portion,
wherein a central portion of the convex light-transmitting portion is thicker than the light-blocking layer.

7. The display apparatus of claim 3, further comprising an overcoat layer over the light-blocking layer and the color filter layer,
wherein a refractive index of the convex light-transmitting portion is higher than that of the overcoat layer.

8. The display apparatus of claim 7, wherein a difference between the refractive index of the convex light-transmitting portion and the refractive index of the overcoat layer is in a range of 0.1 to 0.3.

9. The display apparatus of claim 2, further comprising:
a thin film encapsulation layer covering the light-emitting element and the light-receiving element; and
an input sensing layer between the thin film encapsulation layer and the light-blocking layer.

10. The display apparatus of claim 1, further comprising an input sensing layer over the light-emitting element and the light-receiving element,
wherein the input sensing layer comprises a first conductive layer, a first inorganic insulating layer on the first conductive layer, a second conductive layer on the first inorganic insulating layer, and a second inorganic insulating layer on the second conductive layer,
wherein the first conductive layer comprises a first conductive layer opening overlapping the light-receiving element, and the second conductive layer comprises a second conductive layer opening overlapping the light-receiving element,
wherein the upper layer is at least one of the first conductive layer or the second conductive layer.

11. The display apparatus of claim 10, further comprising a polarizing layer on the input sensing layer.

12. The display apparatus of claim 10, wherein the upper layer is the first conductive layer, the sensing opening is the first conductive layer opening, and the convex light-transmitting portion is arranged in the first conductive layer opening.

13. The display apparatus of claim 12, wherein the first inorganic insulating layer covers the convex light-transmitting portion.

14. The display apparatus of claim 12, wherein a refractive index of the convex light-transmitting portion is higher than that of the first inorganic insulating layer.

15. The display apparatus of claim 14, wherein a difference between the refractive index of the convex light-transmitting portion and the refractive index of the first inorganic insulating layer is in a range of 0.1 to 0.3.

16. The display apparatus of claim 10, wherein the upper layer is the second conductive layer, the sensing opening is the second conductive layer opening, and the convex light-transmitting portion is in the second conductive layer opening.

17. The display apparatus of claim 16, wherein the second inorganic insulating layer covers the convex light-transmitting portion.

18. The display apparatus of claim 16, wherein a refractive index of the convex light-transmitting portion is higher than that of the second inorganic insulating layer.

19. The display apparatus of claim 18, wherein a difference between the refractive index of the convex light-transmitting portion and the refractive index of the second inorganic insulating layer is in a range of 0.1 to 0.3.

20. The display apparatus of claim 10, further comprising a thin film encapsulation layer covering the light-emitting element and the light-receiving element and arranged under the input sensing layer.
